(19) United States
(12) Patent Application Publication
(10) Pub. No.: US 2007/0063239 A1
(43) Pub. Date: Mar. 22, 2007

(54) Semiconductor device

(75) Inventors: Kenji Yamada, Kuwana (JP); Naoya Sashida, Kuwana (JP)

Correspondence Address: HARNESS, DICKEY & PIERCE, P.L.C., P.O. BOX 828, BLOOMFIELD HILLS, MI, 48303, US

(73) Assignees: Seiko Epson Corporation; FUJITSU LIMITED

(21) Appl. No.: 11/522,770

(22) Filed: Sep. 18, 2006

(30) Foreign Application Priority Data
Sep. 21, 2005 (JP) 2005-274033

(51) Int. Cl. H01L 29/94

(52) U.S. Cl. 257/295

(57) ABSTRACT

A semiconductor device includes: a substrate; a first insulating layer formed on the substrate; a groove formed in the first insulating layer; a barrier layer formed on at least a side surface and a bottom surface of the groove; a second insulating layer formed on the barrier layer; a first electrode formed on at least the barrier layer and the second insulating layer; a ferroelectric layer formed over the first electrode; and a second electrode formed over the ferroelectric layer.

Japanese Patent Application No. 2005-274033, filed on Sep. 21, 2005, is hereby incorporated by reference in its entirety.

### BACKGROUND OF THE INVENTION

The present invention relates to a semiconductor device including a first electrode, a ferroelectric layer, and a second electrode.

A ferroelectric memory device (FeRAM) is a nonvolatile memory which can operate at a low voltage and a high speed. Since the memory cell of the ferroelectric memory device can be formed using one transistor and one capacitor (1T/1C), the ferroelectric memory device can be integrated to a degree comparable to that of a DRAM. Therefore, the ferroelectric memory device is expected to be a large-capacity nonvolatile memory.

When electrically connecting the capacitor and the transistor of the ferroelectric memory device, a contact section having a tungsten plug layer is provided on the impurity layer of the transistor, and the capacitor is disposed on the contact section (e.g. JP-A-2003-243621).

The tungsten plug layer may be formed by providing tungsten in a contact hole formed in an insulating layer by sputtering, for example. Accordingly, the tungsten plug layer usually does not have a uniform crystal orientation. Therefore, when forming the capacitor on the tungsten plug layer, the crystal orientation of each layer (first electrode, ferroelectric layer, and second electrode) forming the ferroelectric memory device decreases due to the low crystal orientation of tungsten, whereby the hysteresis characteristics of the ferroelectric memory device may deteriorate.

### SUMMARY

According to one aspect of the invention, there is provided a semiconductor device comprising:

a substrate;

a first insulating layer formed on the substrate;

a groove formed in the first insulating layer;

a barrier layer formed on at least a side surface and a bottom surface of the groove;

a second insulating layer formed on the barrier layer;

a first electrode formed on at least the barrier layer and the second insulating layer;

a ferroelectric layer formed over the first electrode; and

a second electrode formed over the ferroelectric layer.

### BRIEF DESCRIPTION OF THE SEVERAL VIEWS OF THE DRAWING

FIG. 1 is a cross-sectional view schematically showing a semiconductor device according to one embodiment of the invention.

FIG. 2 is a view schematically showing planar patterns of a first electrode, a second electrode, and a second insulating layer shown in FIG. 1.

FIG. 3 is a cross-sectional view schematically showing a manufacturing step of the semiconductor device shown in FIG. 1.

FIG. 4 is a cross-sectional view schematically showing the manufacturing step of the semiconductor device shown in FIG. 1.

FIG. 5 is a cross-sectional view schematically showing the manufacturing step of the semiconductor device shown in FIG. 1.

FIG. 6 is a cross-sectional view schematically showing the manufacturing step of the semiconductor device shown in FIG. 1.

FIG. 7 is a cross-sectional view schematically showing a modification of a semiconductor device according to one embodiment of the invention.

FIG. 8 is a cross-sectional view schematically showing a modification of a semiconductor device according to one embodiment of the invention.

FIG. 9 is a cross-sectional view schematically showing a modification of a semiconductor device according to one embodiment of the invention.

### DETAILED DESCRIPTION OF THE EMBODIMENT

The invention may provide a semiconductor device in which the crystal orientation of each layer forming a ferroelectric capacitor is excellently controlled.

According to one embodiment of the invention, there is provided a semiconductor device comprising:

a substrate;

a first insulating layer formed on the substrate;

a groove formed in the first insulating layer;

a barrier layer formed on at least a side surface and a bottom surface of the groove;

a second insulating layer formed on the barrier layer;

a first electrode formed on at least the barrier layer and the second insulating layer;

a ferroelectric layer formed over the first electrode; and

a second electrode formed over the ferroelectric layer.

In the semiconductor device according to this embodiment, since the first electrode is provided at least on the barrier layer and the second insulating layer, a first electrode which is not affected by the crystal orientation of the lower layer can be formed in comparison with a semiconductor device in which a first electrode is formed on a plug conductive layer formed of tungsten or the like. Moreover, a semiconductor device exhibiting excellent hysteresis characteristics can be obtained by providing the ferroelectric layer over the first electrode.

In this semiconductor device, a connection portion of the barrier layer and the first electrode may be provided outside an overlapping region of the first electrode and the second electrode. In this case, the overlapping region may be disposed directly over the first insulating layer.

In this semiconductor device, the barrier layer may further include an extension portion provided on the first insulating layer. In this case, the extension portion may be provided outside an overlapping region of the first electrode and the second electrode.

This semiconductor device may further include a contact section,

the groove may be formed on the contact section, and

the barrier layer may be connected with the contact section at the bottom surface of the groove.

Some embodiments of the invention will be described below, with reference to the drawings.

1. Semiconductor Device

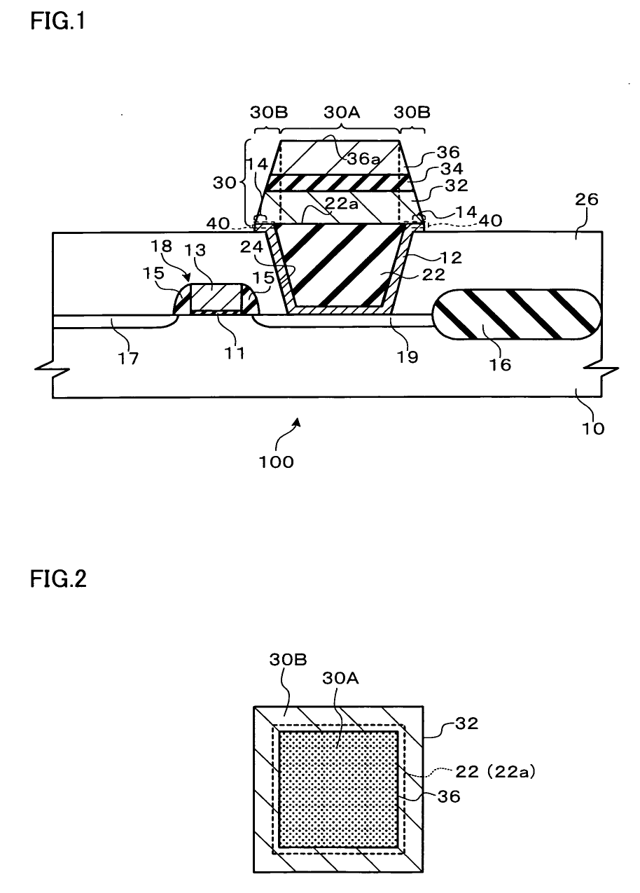

FIG. 1 is a cross-sectional view schematically showing a semiconductor device (ferroelectric memory device) 100 according to one embodiment of the invention. FIG. 2 is a view schematically showing planar patterns of first and second electrodes 32 and 36 and a second insulating layer 22 shown in FIG. 1. In more detail, the outer edge of the first electrode 32 indicates the outer edge of the bottom surface (connection surface of the first electrode 32 with the second insulating layer 22 and a barrier layer 12) of the first electrode 32, the outer edge of the second electrode 36 indicates the outer edge of a top surface 36a of the second electrode 36, and the outer edge of the second insulating layer 22 indicates the outer edge of a top surface 22a of the second insulating layer 22.

As shown in FIG. 1, the semiconductor device 100 includes a ferroelectric capacitor 30 and a switching transistor 18 for the ferroelectric capacitor 30. Although a 1T/1C memory cell is described in this embodiment, the memory cell to which the invention is applied is not limited to the 1T/1C memory cell.

The transistor 18 includes a gate insulating layer 11 provided on a semiconductor substrate 10, a gate conductive layer 13 provided on the gate insulating layer 11, and first and second impurity regions 17 and 19 (source/drain regions). The transistor 18 is embedded in a first insulating layer 26 provided on the semiconductor substrate 10. A groove 24 is formed in the first insulating layer 26 in the region located on the second impurity region 19, and the barrier layer 12 is provided on the bottom surface and the side surface of the groove 24. Specifically, the barrier layer 12 is electrically connected with the switching transistor 18 and the ferroelectric capacitor 30, and has a function of a contact conductive layer of the switching transistor 18 and the ferroelectric capacitor 30. The second insulating layer 22 is formed on the barrier layer 12.

Each of the first and second insulating layers 26 and 22 may be formed of a known insulating material. As examples of the known insulating material, a silicon oxide layer, a silicon nitride layer, a silicon oxynitride layer, a known insulating material used for a Low-k film, and the like can be given.

The ferroelectric capacitor 30 includes the first electrode 32, a ferroelectric layer 34 provided over the first electrode 32, and the second electrode 36 provided over the ferroelectric layer 34. The ferroelectric capacitor 30 is provided on the barrier layer 12 and the second insulating layer 22. Specifically, the first electrode 32 is provided on at least the barrier layer 12 and the second insulating layer 22.

As shown in FIG. 1, the barrier layer 12 includes an extension portion 14. The extension portion 14 is a portion of the barrier layer 12 provided on the first insulating layer 26. Specifically, the barrier layer 12 is provided on the bottom surface and the side surface of the groove 24 and the first insulating layer 26. The contact area of the first electrode 32 and the barrier layer 12 can be increased by providing the extension portion 14 of the barrier layer 12 on the first insulating layer 26.

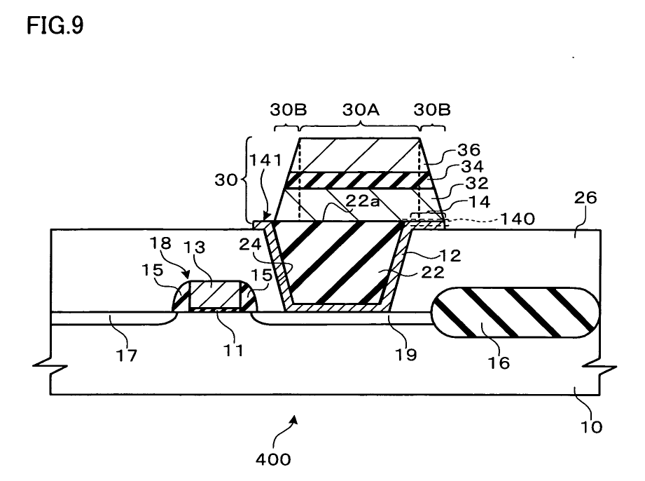

The material for the barrier layer 12 is not particularly limited insofar as the material exhibits conductivity. The barrier layer 12 is preferably formed of a material which exhibits oxygen barrier properties. In a semiconductor device 400 shown in FIG. 9, misalignment occurs between the ferroelectric capacitor 30 and the barrier layer 12 when forming the ferroelectric capacitor 30, whereby the barrier layer 12 is exposed to the outside in an exposure portion 141. In this case, the barrier layer 12 is not oxidized because the barrier layer 12 is provided with oxygen barrier properties. Moreover, the barrier layer 12 and the first electrode 32 can be connected in a connection portion 140. FIG. 9 is a cross-sectional view showing the semiconductor device 400 which is a modification of the semiconductor device 100 according to this embodiment.

As examples of the material for the barrier layer 12, TiAlN, TiAl, TiSiN, TiN, TaN, and TaSiN can be given. It is preferable that the barrier layer 12 be a layer containing titanium, aluminum, and nitrogen (TiAlN).

In the case where the barrier layer 12 is formed of TiAlN, when the composition of the barrier layer 12 is indicated by the chemical formula Ti₍₁₋ₓ₎AlₓN_{y}, the composition (atom ratio) of titanium, aluminum, and nitrogen in the barrier layer 12 preferably satisfies 0<x≦0.4 and 0<y.

The first electrode 32 may be formed of at least one metal selected from platinum, ruthenium, rhodium, palladium, osmium, and iridium. The first electrode 32 is preferably formed of platinum or iridium, and still more preferably formed of iridium. The first electrode 32 may be either a single-layer film or a stacked multilayer film.

The ferroelectric layer 34 includes a ferroelectric substance. The ferroelectric substance has a perovskite crystal structure and may be shown by the general formula AB₁₋ₐXaO₃. In the above general formula, A includes an element such as Pb, Ca, Sr, or La, and B includes an element such as Ti, Zr, Nb, or Mg. X includes at least one of V, Nb, Ta, Cr, Mo, W, Ca, Sr, and Mg. As a typical ferroelectric substance included in the ferroelectric layer 34, PbTi₁₋ₐZrₐO₃ (PZT) can be given. A trace amount of an additional element may be added to this basic structure. SrBi₂Ta₂O₉ (SBT) or (Bi,La)₄Ti₃O₁₂ (BLT) having a crystal structure derived from the perovskite structure may also be used as the above ferroelectric substance.

Of these, PZT is preferable as the material for the ferroelectric layer 34. In this case, it is preferable that the first electrode 32 be formed of iridium from the viewpoint of device reliability.

The second electrode 36 may be formed of the above-mentioned material which may be used for the first electrode 32, or an oxide of the above-mentioned material. Or, the second electrode 36 may be formed of aluminum, silver, nickel, or the like. The second electrode 36 may be either a single-layer film or a stacked multilayer film. The second electrode 36 is preferably formed of platinum or a laminate film of iridium oxide and iridium.

In FIGS. 1 and 2, an overlapping region 30A of the first electrode 32 and the second electrode 36 (hereinafter may be called “region 30A”) refers to a region in which the first electrode 32 and the second electrode 36 overlap through the entire thicknesses of the first electrode 32 and the second electrode 36 and a region positioned perpendicularly under that region.

For example, in the ferroelectric capacitor 30 shown in FIG. 1 which has a rectangular prismoidal shape and in which the top surface 32a of the first electrode 32 is larger than the top surface 36a of the second electrode 36, the region 30A is a region positioned perpendicularly under the top surface 36a of the second electrode 36 (see FIG. 2).

In FIG. 1, the region 30A is a region inside the two dotted lines, and a region 30B is a region outside the two dotted lines. In FIG. 2, the region 30A is a region indicated by the dots, and the region 30B is a region indicated by the diagonal lines.

In other words, the overlapping region 30A of the first electrode 32 and the second electrode 36 is a region of the ferroelectric capacitor 30 which substantially functions as a capacitor (capacitor region).

As shown in FIGS. 1 and 2, the barrier layer 12 and the first electrode 32 are connected in a connection portion 40. The connection portion 40 is a region in which the barrier layer 12 and the first electrode 32 are connected. In more detail, the connection portion 40 is a region enclosed by the dotted line in FIG. 1.

In the semiconductor device 100 according to this embodiment, the connection portion 40 of the barrier layer 12 and the first electrode 32 is provided in a region (region 30B) other than the overlapping region 30A of the first electrode 32 and the second electrode 36. The first electrode 32 can be formed on only the second insulating layer 22 in the region 30A by providing the connection portion 40 of the barrier layer 12 and the first electrode 32 in the region 30B. This allows the first electrode 32 having a single lower layer (second insulating layer 22) to be formed in the capacitor region, whereby a uniform first electrode 32 can be formed. This allows formation of a uniform ferroelectric layer 34, whereby the ferroelectric capacitor 30 can function as a capacitor exhibiting excellent hysteresis characteristics.

In the semiconductor device 100 according to this embodiment, since the first electrode 32 is provided at least on the barrier layer 12 and the second insulating layer 22, a first electrode 32 which is not affected by the crystal orientation of the lower layer can be formed in comparison with a semiconductor device in which a first electrode is formed on a plug conductive layer formed of tungsten or the like. A semiconductor device exhibiting excellent hysteresis characteristics can be obtained by providing the ferroelectric layer 34 over the first electrode 32.

In the ferroelectric memory device 100 according to this embodiment, the overlapping region 30A of the first electrode 32 and the second electrode 36 can be disposed directly over the first insulating layer 22, as shown in FIGS. 1 and 2. Moreover, the extension portion 14 of the barrier layer 12 can be provided in the region 30B other than the overlapping region 30A. This configuration allows the first electrode 32 having a single lower layer (second insulating layer 22) to be formed in the capacitor region, whereby a uniform first electrode 32 can be formed. As a result, a uniform ferroelectric layer 34 can be formed, whereby the ferroelectric capacitor 30 can function as a capacitor exhibiting excellent hysteresis characteristics.

The semiconductor device 100 according to this embodiment has an advantage in that, even if the above-mentioned misalignment has occurred (see FIG. 9), the barrier layer 12 can function as a contact conductive layer for the transistor 18 and the ferroelectric capacitor 30 if the barrier layer 12 is connected with the first electrode 32.

2. Method of Manufacturing Semiconductor Device

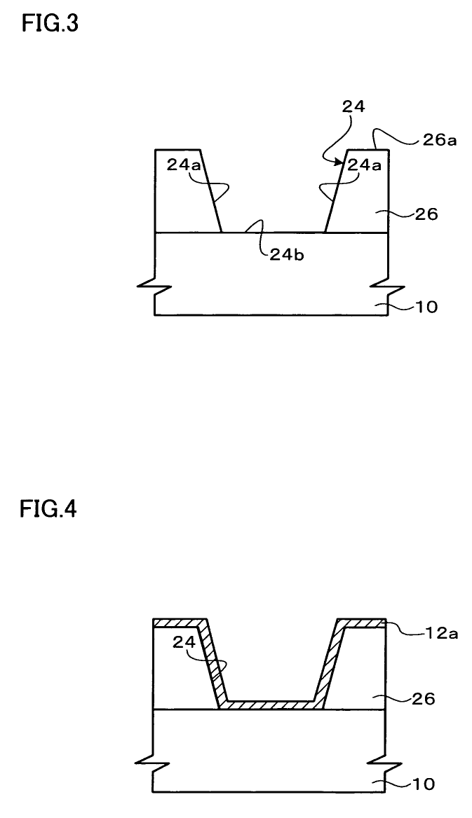

An example of a method of manufacturing the semiconductor device 100 shown in FIG. 1 is described below with reference to the drawings. FIGS. 3 to 6 are cross-sectional views schematically showing manufacturing steps of the semiconductor device 100 shown in FIG. 1. FIGS. 3 to 6 illustrate only the region of the semiconductor device 100 shown in FIG. 1 near the region in which the barrier layer 12 and the ferroelectric capacitor 30 are formed.

The transistor 18 is formed on the semiconductor substrate 10 (see FIG. 1). In more detail, the transistor 18 is formed on the semiconductor substrate 10, and the first insulating layer 26 is stacked on the transistor 18.

The groove 24 is formed in the first insulating layer 26 by dry etching or the like (see FIG. 3). The size of the groove 24 is appropriately determined depending on the size of the ferroelectric capacitor 30 to be formed. The barrier layer 12a is then formed (see FIG. 4). The barrier layer 12a is formed on a side surface 24a and a bottom surface 24b of the groove 24 and a top surface 26a of the first insulating layer 26. The barrier layer 12a may be formed by CVD or sputtering, for example. The second insulating layer 22 is formed on the barrier layer 12a (see FIG. 5). The second insulating layer 22 may be formed by stacking an insulating layer (not shown) on the barrier layer 12a by CVD or the like, and removing part of the insulating layer formed on the first insulating layer 26 by chemical mechanical polishing, for example. In this case, it is preferable to polish the insulating layer so that the top surface of the second insulating layer 22 has a height almost equal to that of the top surface of the barrier layer 12, as shown in FIG. 5.

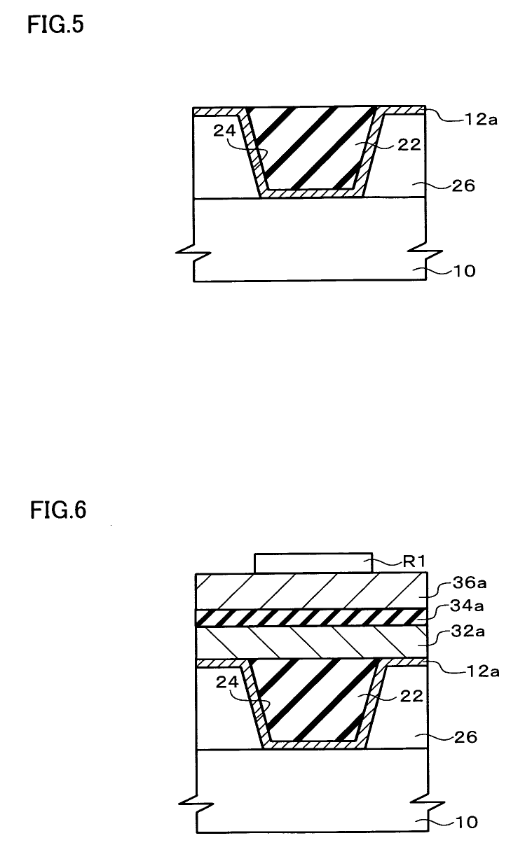

The ferroelectric capacitor 30 is then formed (see FIG. 6).

The first electrode 32a is formed on the barrier layer 12a and the second insulating layer 22. The first electrode 32a may be formed using an arbitrary method depending on the material for the first electrode 32a. For example, the first electrode 32a may be formed by sputtering or CVD.

The ferroelectric layer 34a is formed on the first electrode 32a. The ferroelectric layer 34a may be formed using an arbitrary method depending on the material for the ferroelectric layer 34a. For example, the ferroelectric layer 34a may be formed by a spin-on method, sputtering, or MOCVD.

The second electrode 36a is formed on the ferroelectric layer 34a. The second electrode 36a may be formed using an arbitrary method depending on the material for the second electrode 36a. For example, the second electrode 36a may be formed by sputtering or CVD.

A resist layer R1 with a specific pattern is formed on the second electrode 36a. The barrier layer 12a, the first electrode 32a, the ferroelectric layer 34a, and the second electrode 36a are patterned by photolithography using the resist layer R1 as a mask. The resist R1 has such a pattern that the extension portion 14 of the barrier layer 12 is formed on the first insulating layer 26 after patterning. The semiconductor device 100 including the stacked-type ferroelectric capacitor 30 is thus obtained (see FIG. 1). The ferroelectric capacitor 30 included in the semiconductor device 100 includes the first electrode 32 provided on the barrier layer 12 and the second insulating layer 22, the ferroelectric layer 34 provided on the first electrode 32, and the second electrode 36 provided on the ferroelectric layer 34.

3. Modification

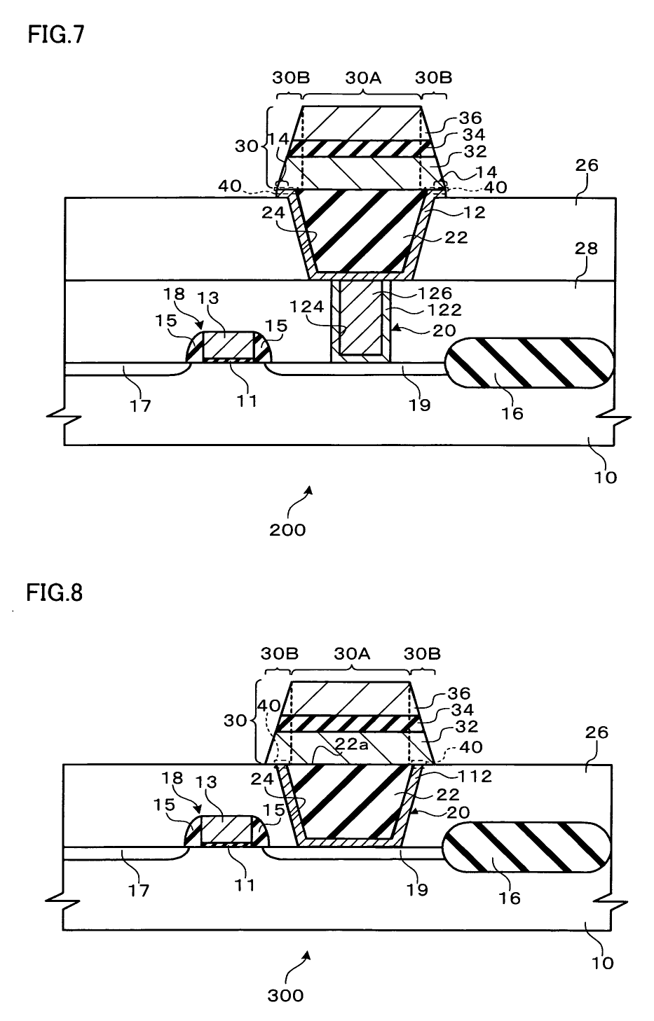

FIGS. 7 and 8 are cross-sectional views schematically showing modifications of the semiconductor device 100 shown in FIG. 1. Semiconductor devices 200 and 300 shown in FIGS. 7 and 8 achieve the same effects as those of the semiconductor device 100 shown in FIG. 1.

3.1. Modification 1

The semiconductor device 200 shown in FIG. 7 has a configuration differing from that of the semiconductor device 100 shown in FIG. 1 in that a contact section 20 is provided under the barrier layer 12 and the second impurity region 19 and the barrier layer 12 are electrically connected through the contact section 20. In the semiconductor device 200 shown in FIG. 7, the remaining elements are the same as those of the semiconductor device 100 shown in FIG. 1. Detailed description of these elements is omitted.

The groove 24 is formed on the contact section 20. The barrier layer 12 is connected with the contact section 20 at the bottom surface of the groove 24.

The contact section 20 includes an opening 124 formed in a third insulating layer 28, a contact barrier layer 122 formed on the side surface and the bottom surface of the opening 124, and a plug conductive layer 126 formed on the contact barrier layer 122. The contact barrier layer 122 may be formed of the above-mentioned material which may be used for the barrier layer 12. The plug conductive layer 126 is formed of a high-melting-point metal such as tungsten, molybdenum, tantalum, titanium, or nickel. The third insulating layer 28 may be formed of the same material as the first insulating layer 26.

3.2. Modification 2

The semiconductor device 300 shown in FIG. 8 has a configuration differing from that of the semiconductor device 100 shown in FIG. 1 in that the barrier layer 12 does not have the extension portion 14. In the semiconductor device 300 shown in FIG. 8, the remaining elements are the same as those of the semiconductor device 100 shown in FIG. 1. Detailed description of these elements is omitted. The semiconductor device 300 shown in FIG. 8 may have a configuration in which the barrier layer 12 and the second impurity region 19 are electrically connected through the contact section 20 in the same manner as the semiconductor device 200 shown in FIG. 7.

Although only some embodiments of the invention have been described in detail above, those skilled in the art will readily appreciate that many modifications are possible in the embodiments without materially departing from the novel teachings and advantages of this invention. Accordingly, all such modifications are intended to be included within the scope of the invention.

For example, the ferroelectric capacitor and the method of manufacturing the same according to the above embodiment may be applied to a capacitor included in a piezoelectric device or the like.

What is claimed is:

1. A semiconductor device comprising:
a substrate;
a first insulating layer formed on the substrate;
a groove formed in the first insulating layer;
a barrier layer formed on at least a side surface and a bottom surface of the groove;
a second insulating layer formed on the barrier layer;
a first electrode formed on at least the barrier layer and the second insulating layer;
a ferroelectric layer formed over the first electrode; and
a second electrode formed over the ferroelectric layer.

2. The semiconductor device as defined in claim 1,
wherein a connection portion of the barrier layer and the first electrode is provided outside an overlapping region of the first electrode and the second electrode.

3. The semiconductor device as defined in claim 1,
wherein the overlapping region is disposed directly over the first insulating layer.

4. The semiconductor device as defined in claim 1,
wherein the barrier layer includes an extension portion provided on the first insulating layer.

5. The semiconductor device as defined in claim 4,
wherein the extension portion is provided outside an overlapping region of the first electrode and the second electrode.

6. The semiconductor device as defined in claim 1, further comprising:
a contact section;
wherein the groove is formed on the contact section; and
wherein the barrier layer is connected with the contact section at the bottom surface of the groove.
